(19) United States
(12) Patent Application Publication
(10) Pub. No.: US 2005/0114054 A1
(43) Pub. Date: May 26, 2005

(54) Method for analyzing power supply noise of semiconductor integrated circuit

(76) Inventors: Kenji Shimazaki, Kobe (JP); Kazuhiro Sato, Neyagawa (JP); Takahiro Ichinomiya, Katano (JP); Shozo Hirano, Osaka (JP); Masao Takahashi, Osaka (JP); Hiroyuki Tsujikawa, Kusatsu (JP); Seijiro Kojima, Kyoto (JP)

Correspondence Address: MCDERMOTT WILL & EMERY LLP, 600 13TH STREET, N.W., WASHINGTON, DC, 20005-3096, US

(21) Appl. No.: 10/988,833

(22) Filed: Nov. 16, 2004

(30) Foreign Application Priority Data
Nov. 26, 2003 (JP) 2003-396214

(51) Int. Cl. H03K 17/16

(52) U.S. Cl. 702/69

(57) ABSTRACT

Based on design data of a semiconductor integrated circuit, an impedance related to a power supply wire is calculated, and based on the calculated impedance, a frequency characteristic of power supply noise is analyzed. In calculation of an impedance, an impedance between power supplies which are different in potential, e.g., a main power supply and a ground, may be calculated. Alternatively, an impedance between power supplies which are substantially the same in potential, e.g., a main power supply and an N-well power supply, may be calculated. The calculated impedance includes a wire capacitance between power supply wires, a substrate resistance, an impedance of a package connected to the power supply wires, and so on. Thus, it is possible to provide a method for analyzing power supply noise of a semiconductor integrated circuit, which can be executed at an early stage of a design process with a small amount of calculation.

### BACKGROUND OF THE INVENTION

1. Field of the Invention

The present invention relates to a method for analyzing power supply noise of a semiconductor integrated circuit, and more specifically to a method for analyzing power supply noise of a semiconductor integrated circuit which is applicable to a semiconductor integrated circuit in which an additional power supply is used to control voltage applied to a circuit substrate.

2. Description of the Background Art

In a known method for allowing a semiconductor integrated circuit to operate at high speed, an additional power supply different from a main power supply for providing a power and a ground is used to control voltage applied to a circuit substrate. Note that “substrate voltage” as described herein refers to a potential which confronts a potential of a gate, which controls the amount of electric charge in a channel of a transistor, and refers to a well voltage in the case of a transistor provided within a well. FIGS. 17A and 17B are diagrams showing the structure of a CMOS inverter in which an additional power supply is used to control voltage applied to a circuit substrate. As shown in FIG. 17A, this CMOS inverter includes a P-channel transistor 91 and an N-channel transistor 92. These two transistors each have, in addition to three terminals (i.e., source, drain, and gate terminals), a substrate terminal as a fourth terminal. The drain terminals of the two transistors are connected to each other, and the source terminal of the P-channel transistor 91 and the source terminal of the N-channel transistor 92 are connected respectively to a power supply VDD and a ground VSS. The substrate terminal of the P-channel transistor 91 is connected to an N-well power supply VSUBN, and the substrate terminal of the N-channel transistor 92 is connected to a P-substrate power supply VSUBP.

FIG. 17B is a diagram showing across-sectional structure of the CMOS inverter. As shown in FIG. 17B, an N-well 94 is provided on one surface of a substrate 93, and the P-channel transistor 91 and the N-channel transistor 92 are provided respectively within the N-well 94 and on the substrate 93. In addition, in the N-well 94, a well contact 95 is provided as the substrate terminal of the P-channel transistor 91, whereas on the substrate 93, a substrate contact 96 is provided as the substrate terminal of the N-channel transistor 92. In many conventional semiconductor integrated circuits, a common power supply is used as the power supply VDD and the N-well power supply VSUBN. In semiconductor integrated circuits of recent years, however, separate power supplies which are substantially the same but different in potential are often used as the power supply VDD and the N-well power supply VSUBN, in order to achieve high-speed operation, for example. Transistors that operate at high speed usually have a triple-well structure, but for simplification of explanation, a transistor having a twin-well structure is described here.

FIGS. 18A to 18C are graphs showing results obtained by measuring power supply voltage applied to a semiconductor integrated circuit in which an additional power supply is used to control voltage applied to its circuit substrate. The graphs of FIGS. 18A to 18C show how potentials of the power supply VDD (solid lines) and the N-well power supply VSUBN (dashed lines) fluctuate at clock signal frequencies of 50 MHz, 100 MHz, and 200 MHz. From the measurement results shown in FIGS. 18A to 18C, it is apparent that a relative relationship between power supply noise (i.e., potential fluctuation) of the power supply VDD and that of the N-well power supply VSUBN varies with the clock signal frequency in a nonlinear manner. For example, in the case where the clock signal frequency is 100 MHz, the power supply noise of the N-well power supply VSUBN fluctuates more sharply than can be expected from the measurement results obtained in the cases where the clock signal frequencies are 50 MHz and 200 MHz.

If the power supply noise varies with the clock signal frequency in a nonlinear manner as described above, the operating frequency of the semiconductor integrated circuit might coincide with a frequency at which the power supply noise increases. If the semiconductor integrated circuit is caused to operate with such a frequency, power supply noise might increase to change the threshold value and operating current of a transistor, so that a delay value and an output potential of the transistor are changed, resulting in malfunction of the transistor. Further, in semiconductor integrated circuits of recent years, with the progress of a fine process technology, it is required to lower power supply voltage. Also, the amount of current flowing through a circuit is increased with the number of transistors. Because of the above reasons, in the semiconductor integrated circuits of recent years, the design margin in relation to power supply fluctuation tends to be insufficient.

Conventionally known methods for analyzing power supply noise of a semiconductor integrated circuit employ an IR-DROP analysis tool or a substrate noise analysis tool. The IR-DROP analysis tool estimates a voltage drop of a power supply wire by means of circuit simulation. In a method using the IR-DROP analysis tool, firstly, power supply resistances Rs and a decoupling capacitance Cd between a power supply and a ground (see FIG. 19) are extracted by using a Layout Parasitic Extraction (LPE) tool. Next, after inductances Lp of a package and soon are added, current and voltage within the circuit are estimated by using a method as used in, for example, a SPICE simulator, for performing transient analysis of an RLC circuit including a transistor. Then, waveforms showing potential fluctuations (i.e., noise) of the power supply and the ground are created based on the estimated current and voltage. In the case of a high-frequency circuit, inductance of an on-chip power supply also affects power supply noise, and therefore might be taken into consideration for the analysis.

The LPE tool extracts wiring resistance, inter-wire capacitance, and inductance of the semiconductor integrated circuit in the following manner. For example, the LPE tool extracts wires having a three-dimensional structure as shown in FIG. 20 from layout information of the semiconductor integrated circuit, and determines the material of the wires. The potential of each wire is calculated based on voltage applied from the outside of the semiconductor integrated circuit and electrical conductivity of the material of the wire. The wiring resistance is calculated based on resistance density of the material of the wire and the size of the wire. The inter-wire capacitance is calculated only for two wires having different potentials, based on an area S of opposing portions of the wires, a distance d between the wires (see FIG. 20), and a dielectric constant of a material that fills space between the wires. The reason that the inter-wire capacitance is calculated only for the two wires having different potentials is to distinguish the wires from a parasitic element, which affects a result of calculation of delay time of a transistor. Also, it is possible to extract inductance from circuit information in a manner as described above.

The substrate noise analysis tool analyzes noise of a substrate based on current between a power supply and a ground in an ideal condition and substrate resistance. For example, the substrate noise analysis tool uses a circuit model as shown in FIG. 21. The substrate resistance and well resistance are calculated based on resistance density. Junction capacitance is calculated by multiplying per-unit-area junction capacitance by a total area of junctions.

Besides the aforementioned methods for analyzing power supply noise of a semiconductor integrated circuit, there are known methods for analyzing power supply noise of a printed circuit board. For example, Japanese Laid-Open Patent Publication No. 2001-175702 discloses a method utilizing an AC analysis for adjusting decoupling capacitance that is to be provided in a printed circuit board (see FIG. 22).

However, the aforementioned methods for analyzing power supply noise have the following problems. The method utilizing the IR-DROP analysis tool has the following problems: (1) An analysis cannot be performed until a layout process and then design in its entirety including transistors are completed; (2) Considerable calculation time is needed because all elements, including transistors, that are included in a circuit are taken into consideration for calculation; (3) Effect caused to noise by a parasitic element between points of the same potential cannot be analyzed, because only a parasitic element between points of different potentials is analyzed; and (4) Because substrate impedance is assumed to be zero, which is an ideal value, the effect of the substrate impedance on noise cannot be analyzed. As will be described later, the present invention uses a circuit model in which even wires having the same potential may experience different levels of potential fluctuation. Accordingly, information as extracted using a conventional LPE tool cannot be used as it is.

A method utilizing the substrate noise analysis tool has the following problems: (1) Although impedance of a package which is related to a power supply wire that directly controls a substrate and a well is taken into consideration, neither impedance of a package which is related to a power supply wire that does not directly control the substrate or the well (i.e., a power supply wire that is connected to a source or drain terminal of a transistor) nor impedance of a power supply on a semiconductor substrate is taken into consideration (specifically, the impedance of the power supply on the semiconductor substrate is ignored, for the reason that the impedance of the package is sufficiently larger than the impedance of the power supply on the semiconductor substrate); and (2) Since current flowing from/to a power supply and a ground connected to the source terminal of the transistor is not taken into consideration, an analysis is conducted without considering that noise is amplified through the source terminal connected to the power supply and the ground (specifically, although current flows through a substrate contact without being affected, the current is affected by a source terminal and a drain terminal through a junction capacitance. Accordingly, the effect thereof is ignored for the reason that the effect is sufficiently small).

The method disclosed in Japanese Laid-Open Patent Publication No. 2001-175702 has the following problems: (1) Since a power supply wire within a semiconductor integrated circuit is not taken into consideration, the method cannot be applied to a power supply noise analysis of a semiconductor integrated circuit; and (2) Placing a pass capacitor outside a chip to take countermeasures against noise does not satisfactorily prevent the semiconductor integrated circuit from malfunctioning.

### SUMMARY OF THE INVENTION

Therefore, an object of the present invention is to provide a method for analyzing power supply noise of a semiconductor integrated circuit, which can be executed at an early stage of design with a small amount of calculation and which is applicable to a semiconductor integrated circuit in which an additional power supply is used to control voltage of a circuit substrate.

The present invention has the following features to attain the object above.

A method for analyzing power supply noise of a semiconductor integrated circuit according to the present invention comprises: an impedance calculation step of calculating an impedance related to a power supply wire based on design data of the semiconductor integrated circuit; and an analysis step of analyzing a frequency characteristic of the power supply noise based on the calculated impedance.

Preferably, the impedance calculation step calculates an impedance of a path including two or more power supply wires in the semiconductor integrated circuit. In the case where the semiconductor integrated circuit has a first power supply wire having a relatively high potential and a second power supply wire having a relatively low potential, the impedance calculation step may calculate an impedance of a path including the first and second power supply wires. In the case where the semiconductor integrated circuit has the first and second power supply wires, and a third power supply wire having a potential substantially equal to that of the first power supply wire, the impedance calculation step may calculate an impedance of a path including the first and third power supply wires. In the case where the semiconductor integrated circuit has the first and second power supply wires, and a third power supply wire having a potential substantially equal to that of the second power supply wire, the impedance calculation step may calculate an impedance of a path including the second and third power supply wires.

Also, the impedance calculation step may calculate an impedance including an inter-wire capacitance or a substrate impedance that exists on a path including two or more power supply wires, and also may calculate an impedance including an impedance of a package or a printed circuit board that is connected to two or more supply wires. Also, the impedance calculation step may calculate an impedance of a path including two or more power supply wires that are separated by a resistance element, a substrate resistance, a capacitance element, a junction capacitance, or a well capacitance.

Also, the impedance calculation step may extract an impedance of a path including two or more power supply wires, based on power supply wire structure information. In the case where the semiconductor integrated circuit has the first and second power supply wires, and a third power supply wire having a potential substantially equal to that of the first power supply wire, the impedance calculation step may extract an impedance of a path including the first and third power supply wires, based on the power supply wire structure information. Also, in the case where the semiconductor integrated circuit has the first and second power supply wires, and a third power supply wire having a potential substantially equal to that of the second power supply wire, the impedance calculation step may extract an impedance of a path including the second and third power supply wires, based on the power supply wire structure information.

Also, the impedance calculation step may combine impedances of partial circuits based on a predetermined circuit model to calculate an impedance of a path including two or more power supply wires.

Also, the analysis step may calculate, based on a calculated impedance, a resonance frequency of the semiconductor integrated circuit. Also, the analysis step may calculate, based on the calculated impedance, at least either a range of capacitance values or a range of inductance values, such that a resonance frequency of the semiconductor integrated circuit is kept out of a preset prohibited range. In this case, the prohibited range is set so as to include at least either an operating frequency or a harmonic frequency of the semiconductor integrated circuit.

Also, the analysis step may calculate, based on the calculated impedance, a frequency range that keeps the power supply noise within a predetermined range of levels, and determine an operating frequency of the semiconductor integrated circuit from within the calculated frequency range. Also, based on the calculated impedance, the analysis step may calculate, with respect to at least one member selected from the group consisting of capacitance, inductance, and resistance values, a range which keeps the power supply noise within a predetermined range of levels in a preset frequency range. In these cases, the predetermined range of levels may change based on a delay constraint of a circuit design.

In the method for analyzing power supply noise according to the present invention, a frequency characteristic of the power supply noise is analyzed based on an impedance related to a power supply wire. Therefore, if a floor planning process has been completed and the structure of the power supply wire has been obtained, the process of power supply noise analysis can be performed even without a layout process having been completed. In addition, because only power supply wires are subjected to analysis, the process of power supply noise analysis can be performed with a small amount of calculation.

In addition, calculation of an impedance between power supply wires which are different in potential makes it possible to analyze, for example, power supply noise that is to be generated between a power supply and a ground. In addition, calculation of an impedance between power supply wires which are substantially the same in potential makes it possible to analyze, for example, power supply noise that is to be generated between a power supply and a substrate power supply or between a ground and a substrate ground in a semiconductor integrated circuit in which an additional power supply is used to control a circuit substrate voltage.

In addition, by calculating an impedance including an inter-wire capacitance and a substrate impedance, it is made possible to analyze power supply noise which is not analyzable by using conventional circuit models, i.e., power supply noise that is to be generated between power supplies which are substantially the same in potential. In addition, by calculating an impedance including impedances of a package, a printed circuit board, etc., it is made possible to analyze power supply noise of a semiconductor integrated circuit which would be generated under the actual operating environment. In addition, by calculating an impedance between power supply wires separated by any one of a resistance element, a substrate resistance, a capacitive element, a junction capacitance, and a well capacitance, it is made possible to analyze power supply noise of various kinds of semiconductor integrated circuits, including analog circuits.

In addition, extracting an impedance between power supply wires based on power supply wire structure information makes it possible to automatically calculate the impedance. Extracting an impedance between power supply wires which are substantially the same in potential has the same effect. In addition, calculating an impedance between power supply wires by combining impedances of partial circuits makes it possible to easily calculate an impedance related to a semiconductor integrated circuit composed of a plurality of components.

In addition, by calculating a resonance frequency based on a calculated impedance, it is made possible to obtain a clock signal frequency at which power supply noise is maximized, without conducting power supply noise analysis with respect to a whole range of frequencies for which the analysis is to be conducted. In addition, by obtaining, based on a calculated impedance, a capacitance value or the like which keeps a resonance frequency out of a prohibited range, it is made possible to perform a circuit design, the choice of a package, the design of a printed circuit board, and so on in accordance with the obtained value.

In addition, by determining an operating frequency of a semiconductor integrated circuit based on a calculated impedance, it is made possible to ensure that power supply noise of the semiconductor integrated circuit falls within a predetermined range of levels. In addition, by obtaining, based on a calculated impedance, a capacitance value or the like which keeps power supply noise within a predetermined range of levels in a predetermined frequency range, it is made possible to perform a circuit design, the choice of a package, the design of a printed circuit board, and so on in accordance with the obtained value. In addition, by changing the aforementioned predetermined range of levels based on a delay constraint of a circuit design, it is made possible to change the strictness of a power supply noise analysis in accordance with the strictness of the delay constraint.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a structure of a power supply noise analysis apparatus which executes a method for analyzing power supply noise according to an embodiment of the present invention;

FIG. 2 is a diagram showing a first circuit model which is used in the apparatus shown in FIG. 1;

FIG. 3 is a diagram showing a second circuit model which is used in the apparatus shown in FIG. 1;

FIG. 4 is a block diagram showing the details of a first structure of the apparatus shown in FIG. 1;

FIG. 5 is a diagram for explaining power supply wire structure data used in the apparatus shown in FIG. 1;

FIG. 6 is a diagram for explaining substrate structure data used in the apparatus shown in FIG. 1;

FIG. 7 is a diagram for showing a power supply impedance calculated by the apparatus shown in FIG. 1;

FIG. 8 is a diagram for showing a substrate impedance calculated by the apparatus shown in FIG. 1;

FIG. 9 is a diagram for showing a package impedance calculated by the apparatus shown in FIG. 1;

FIG. 10 is a graph showing an analysis result given by the apparatus shown in FIG. 1;

FIG. 11 is a graph showing other analysis results given by the apparatus shown in FIG. 1;

FIG. 12 is a block diagram showing the details of a second structure of the apparatus shown in FIG. 1;

FIG. 13 is a block diagram showing the details of a third structure of the apparatus shown in FIG. 1;

FIG. 14 is a block diagram showing the details of a fourth structure of the apparatus shown in FIG. 1;

FIG. 15 is a block diagram showing the details of a fifth structure of the apparatus shown in FIG. 1;

FIG. 16 is a block diagram showing the details of a sixth structure of the apparatus shown in FIG. 1;

FIGS. 17A and 17B are diagrams showing a structure of a CMOS inverter in which an additional power supply is used to control a substrate voltage;

FIGS. 18A to 18C are graphs showing power supply noise of a semiconductor integrated circuit in which an additional power supply is used to control the substrate voltage;

FIG. 19 is a diagram showing a circuit model used in a conventional IR-drop analysis tool;

FIG. 20 is a diagram showing a wire model used in a conventional LPE tool;

FIG. 21 is a diagram showing a circuit model used in a conventional substrate noise analysis tool; and

FIG. 22 is a flowchart showing a conventional method for analyzing power supply noise of a printed circuit board.

### DESCRIPTION OF THE PREFERRED EMBODIMENTS

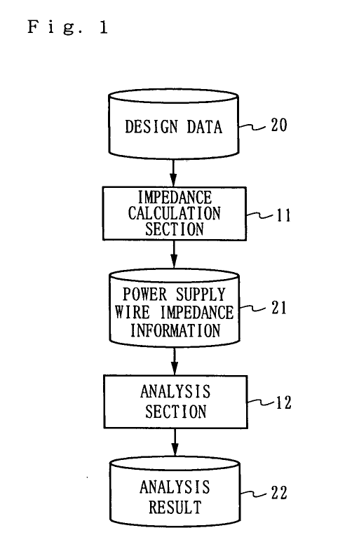

FIG. 1 is a block diagram showing a structure of a power supply noise analysis apparatus which executes a method for analyzing power supply noise of a semiconductor integrated circuit according to an embodiment of the present invention. The power supply noise analysis apparatus shown in FIG. 1 includes an impedance calculation section 11 and an analysis section 12. Design data 20 of a semiconductor integrated circuit to be subjected to analysis is inputted to the power supply noise analysis apparatus. The impedance calculation section 11 calculates impedance of a power supply wire based on the inputted design data 20, and outputs the result as power supply wire impedance information 21. The analysis section 12 analyzes a frequency characteristic of power supply noise based on the power supply wire impedance information 21, and outputs the result as an analysis result 22.

The impedance calculation section 11 calculates impedance of a path including two or more power supply wires of the semiconductor integrated circuit. For example, consider a case where the semiconductor integrated circuit has a first power supply wire (hereinafter referred to as a “high-potential wire”) having a relatively high potential and a second power supply wire (hereinafter referred to as a “ground wire”) having a relatively low potential. In this case, the impedance calculation section 11 may calculate impedance of a path including the high-potential wire and the ground wire. Also, consider a case where the semiconductor integrated circuit has, in addition to the high-potential wire and the ground wire, a power supply wire which is connected to a circuit substrate and has substantially the same potential as that of the high-potential wire (hereinafter referred to as a “substrate high-potential wire”). In this case, the impedance calculation section 11 may calculate impedance of a path including the high-potential wire and the substrate high-potential wire which are substantially the same in potential as each other. Also, consider a case where the semiconductor integrated circuit has, in addition to the high-potential wire and the ground wire, a power supply wire which is connected to the circuit substrate and has substantially the same potential as that of the ground wire (hereinafter referred to as a “substrate ground wire”). In this case, the impedance calculation section 11 may calculate impedance of a path including the ground wire and the substrate ground wire which are substantially the same in potential as each other.

The impedance calculation section 11 combines impedances calculated for partial circuits with reference to a predetermined circuit model, thereby calculating impedance of a path including two or more power supply wires. Circuit models used in the impedance calculation section 11 are described below.

Analysis of the frequency characteristic of power supply noise requires at least information that makes it possible to recognize that an inductance and a capacitance are included in a circuit which is to be subjected to the analysis and that a capacitive impedance is smaller than a resistance impedance which is connected in parallel with the capacitive impedance. In addition, in order to conduct a power supply noise analysis in the course of circuit design and thereby to reflect an analysis result in the circuit design, it is desirable that the power supply noise analysis can be carried out in a floor planning phase of a semiconductor integrated circuit.

However, conventional circuit models have the following disadvantages: (1) A parasitic element between wires being the same in potential as each other is not extracted; (2) A netlist in which impedance of a substrate is connected with impedance of a power supply is not extracted (specifically, in an analysis of the power supply, a substrate terminal is short-circuited, whereas in an analysis of a substrate, the impedance of the power supply is assumed to be zero, which is an ideal value); and (3) An analysis is conducted with reference to transistors, and therefore cannot be carried out before completion of layout, resulting in a long processing time. Therefore, in the present embodiment, in order to conduct an analysis of the frequency characteristic of power supply noise in an early stage of design with a small amount of calculation, a new circuit model for calculating impedance of a power supply wire is used.

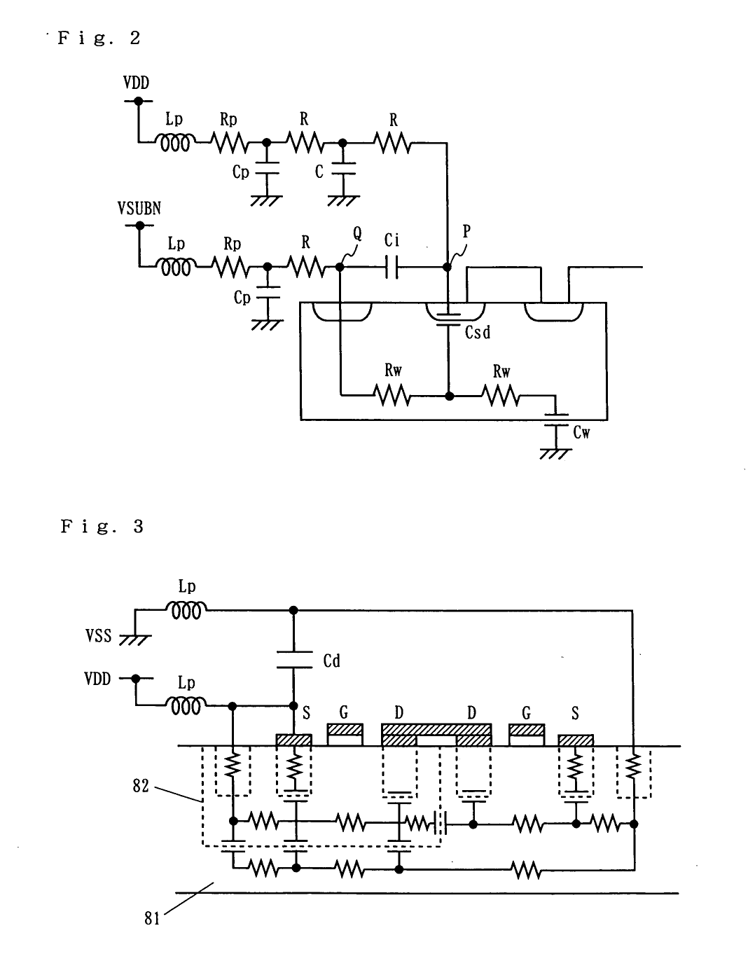

FIG. 2 is a diagram showing a first circuit model used in the impedance calculation section 11. The circuit model shown in FIG. 2 is used to calculate impedance of a path including a high-potential wire for providing a power supply VDD and a substrate high-potential wire for providing an N-well power supply VSUBN. This circuit model is characterized by including inductances Lp of a package connected to the two power supply wires, a wire capacitance Ci between the two power supply wires (i.e., a wire capacitance between the power supply VDD and the N-well power supply VSUBN), and well resistances Rw between the two power supply wires (i.e., well resistances between the power supply VDD and the N-well power supply VSUBN). The use of a circuit model that includes at least these three elements makes it possible to analyze power supply noise between power supplies that are substantially the same in potential as each other, which cannot be analyzed using conventional circuit models. Note that in the case where a value of the wire capacitance Ci is small (i.e., the impedance is large), a junction capacitance Csd and a well capacitance Cw affect the power supply noise. In such a case, analysis is required to be conducted with consideration of the junction capacitance Csd and the well capacitance Cw.

Note that, instead of or in addition to the inductances Lp of the package, impedance of a printed circuit board on which a semiconductor integrated circuit is mounted may be used. Also, impedance of an element which is placed close to a chip on the printed circuit board may be taken into consideration. As such, by calculating an impedance including impedances of a package, a printed circuit board, etc., it becomes possible to analyze power supply noise of a semiconductor integrated circuit, which would be generated under the actual operating environment. Also, if a required precision of an analysis result is not high, the well resistances Rw may be regarded as being infinite resistances.

The impedance calculation section 11 calculates impedance of a path including a high-potential wire and a substrate high-potential wire based on the circuit model as shown in FIG. 2. The analysis section 12 uses, for example, an AC analysis function of a SPICE simulator to calculate a voltage amplification ratio of a point Q to a point P (shown in FIG. 2), while changing a clock signal frequency. When the clock signal frequency reaches a particular value (i.e., a resonance frequency), the wire capacitance Ci between the power supply VDD and the N-well power supply VSUBN resonates with the inductances Lp of the package, resulting in an increase of the power supply noise.

Note that, in the case of calculating impedance of a path including a ground wire and a substrate ground wire, the impedance calculation section 11 may use a circuit model, which is similar to the circuit model shown in FIG. 2 and includes inductances of a package connected to two power supply wires, a wire capacitance between the two power supply wires (i.e., a wire capacitance between a ground and a substrate ground), and a substrate impedance between the two power supply wires (i.e., a substrate resistance, a well capacitance, and a junction capacitance between the ground and the substrate ground).

FIG. 3 is a diagram showing a second circuit model used in the impedance calculation section 11. The circuit model shown in FIG. 3 is used to calculate impedance of a path including a high-potential wire for providing a power supply VDD and a ground wire for providing a ground VSS. This model is characterized by including inductances Lp of a package connected to the two power supply wires, a decoupling capacitance Cd between the two power supply wires (i.e., a decoupling capacitance between the power supply and the ground), and a combined impedance of a substrate 81 and an N-well 82 (which includes a diffusion resistance, a junction capacitance, an N-well resistance, and a substrate resistance). Note that, if a required precision of an analysis result is not high, the combined impedance of the substrate 81 and the N-well 82 may be regarded as being infinite resistance.

The impedance calculation section 11 calculates the impedance of the path including the high-potential wire and the ground wire based on the circuit model as shown in FIG. 3. The analysis section 12 analyzes a frequency characteristic of power supply noise in a manner similar to that used for the circuit model shown in FIG. 2. When the clock signal frequency reaches a particular value (i.e., a resonance frequency), the decoupling capacitance Cd between the power supply and the ground resonates with the inductances Lp of the package, resulting in an increase of the power supply noise.

To summarize the foregoing, the impedance calculation section 11 calculates impedance of a path including two or more power supply wires, which may be a set of a high-potential wire and a ground wire, a set of a high-potential wire and a substrate high-potential wire which are substantially the same in potential, or a set of a ground wire and a substrate ground wire which are substantially the same in potential. Also, the impedance calculation section 11 may calculate inter-wire capacitance that exists on the path including two or more power supply wires (specifically, a wire capacitance Ci between a power supply and an N-well power supply (FIG. 2), a wire capacitance between a ground and a substrate ground, or a decoupling capacitance Cd between a power supply and a ground (FIG. 3)). Also, the impedance calculation section 11 may calculate impedance including substrate impedance (specifically, a well resistance Rw (FIG. 2), a substrate resistance between a ground and a substrate ground, a well capacitance, a junction capacitance, and a combined impedance of the substrate 81 and the N-well 82 (FIG. 3)) that exists on the path including two or more power supply wires. Also, the impedance calculation section 11 may calculate impedance including inductances Lp of a package connected to the two or more power supply wires (and/or impedance of a printed circuit board).

Also, instead of calculating the impedance of the path including two or more power supply wires separated by a substrate resistance or a well capacitance, the impedance calculation section 11 may calculate impedance of a path including two or more power supply wires separated by a resistance element or a capacitive element. Some analog semiconductor integrated circuits include two or more power supply wires separated by a resistance element, and some semiconductor integrated circuits include two or more power supply wires separated by a capacitive element such as a coupling capacitance. Also in the cases of the above semiconductors, the impedance calculation section 11 may calculate impedance of a path including two or more power supply wires using a circuit model that has characteristics similar to those of the circuit models as shown in FIG. 2 and FIG. 3. As such, by calculating impedance between power supply wires separated by any one of a resistance element, a substrate resistance, a capacitive element, a junction capacitance, and a well capacitance, it becomes possible to analyze power supply noise of various kinds of semiconductor integrated circuits, including analog circuits.

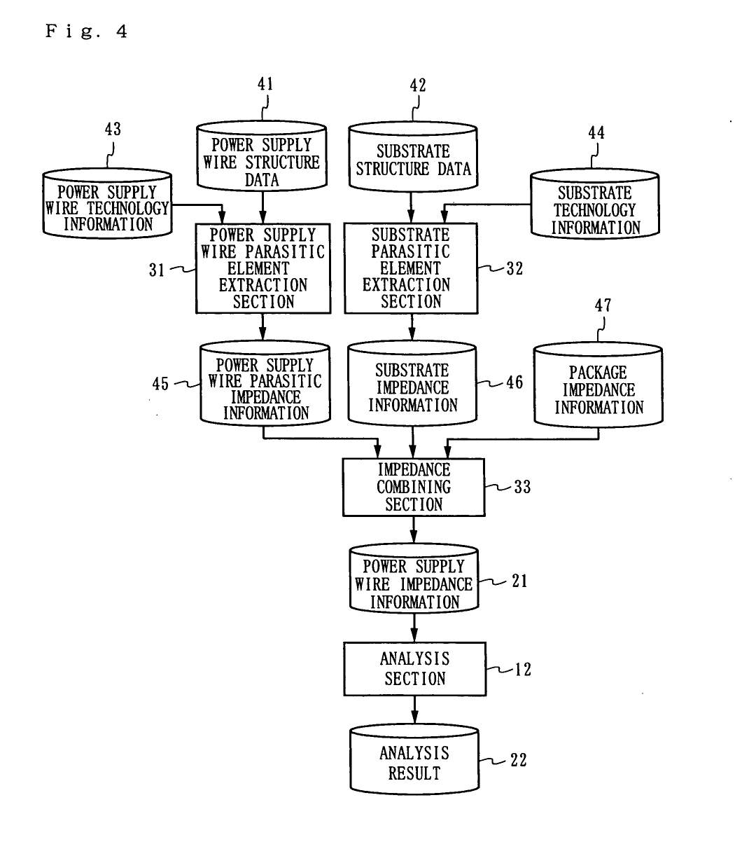

With reference to FIGS. 4 to 9, the details of the impedance calculation section 11 are described below. FIG. 4 is a block diagram showing the details of a structure (a first structure) of the power supply noise analysis apparatus shown in FIG. 1. In FIG. 4, power supply wire structure data 41 and substrate structure data 42 correspond to the design data 20 shown in FIG. 1, and a power supply wire parasitic element extraction section 31, a substrate parasitic element extraction section 32, and an impedance combining section 33 correspond to the impedance calculation section 11 shown in FIG. 1.

The power supply wire structure data 41 is data concerning a power supply wire structure of a semiconductor integrated circuit after a floor planning or layout process. The power supply wire structure data 41 includes power supply wire coordinate data represented by a structure in which two-dimensional wires are stacked or a three dimensional structure (see FIG. 5). FIG. 5 shows an exemplary structure where a high-potential wire for providing a power supply VDD and a substrate high-potential wire for providing an N-well power supply VSUBN run side by side. These two power supply wires are connected at connection points 85 to a substrate 83 and an N-well 84, respectively. The use of the power supply wire structure data 41 as described above makes it possible to obtain a running distance in which two power supply wires (selected from a high-potential wire, a ground wire, a substrate high-potential wire, and a substrate ground wire) run side by side, and to obtain coordinates of points at which the two power supply wires are connected to a substrate, an N-well, or a source terminal. Note that, when obtaining the running distance, wires connected by vias are treated as a single wire.

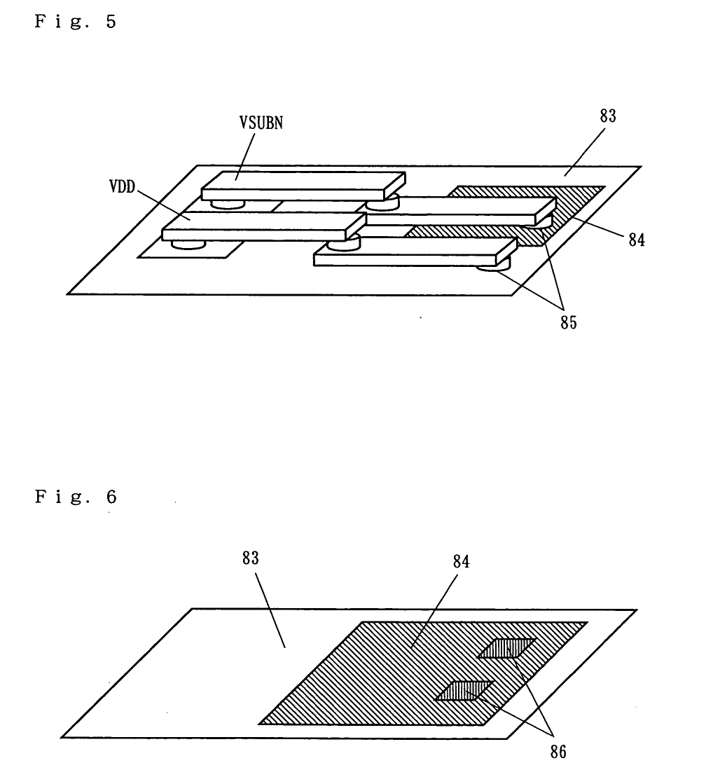

The substrate structure data 42 is data concerning the substrate structure of a semiconductor integrated circuit after a floor planning or layout operation. The substrate structure data 42 includes coordinates of substrate and well contacts, the size and coordinates of a well, the size and coordinates of a diffusion layer of a source terminal, and so on (see FIG. 6). FIG. 6 shows an exemplary structure where the N-well 84 is provided in the substrate 83, and two contacts 86 are provided in the N-well 84. Note that in the power supply noise analysis apparatus shown in FIG. 4, the power supply wire structure data 41 and the substrate structure data 42 are assumed to be separate types of data, but they can be treated as one unit of data.

Referring to FIG. 4, power supply wire technology information 43 includes resistance densities of power supply wires (including a high-potential wire, a ground wire, a substrate high-potential wire, and a substrate ground wire) and dielectric constants of materials between the wires. Substrate technology information 44 includes resistance densities of a substrate and a well, and a PN junction capacitance.

The power supply wire parasitic element extraction section 31 extracts power supply wire parasitic impedance information 45, based on the power supply wire structure data 41 and the power supply wire technology information 43. More specifically, in the case of two power supply wires that are different in potential (e.g., a high-potential wire and a ground wire), the power supply wire parasitic element extraction section 31 uses the same method as that used in a LPE tool to extract a parasitic capacitance between the two power supply wires. In the case of two power supply wires that are substantially the same in potential (e.g., a high-potential wire and a substrate high-potential wire), the power supply wire parasitic element extraction section 31 provides the LPE tool with data that causes the LPE tool to falsely recognize the two power supply wires as being different in potential and thereby extracts a parasitic capacitance between the two power supply wires. In addition, the power supply wire parasitic element extraction section 31 calculates a resistance (i.e., a power supply impedance) of each power supply wire based on the length of the power supply wire, and also calculates coordinates of connections to the substrate. In this manner, the power supply wire parasitic element extraction section 31 extracts, for example, a power supply impedance of a path which includes a high-potential wire for providing a power supply VDD and a substrate high-potential wire for providing an N-well power supply VSUBN, as shown in FIG. 7.

The substrate parasitic element extraction section 32 obtains substrate impedance information 46, based on the substrate structure data 42 and the substrate technology information 44. More specifically, the substrate parasitic element extraction section 32 calculates a resistance value based on the resistance densities of the substrate and the well and a distance between contacts. The substrate parasitic element extraction section 32 also calculates a capacitance value based on a PN junction capacitance and a capacitance of a joint surface that exists between the contacts. The thus-calculated resistance and capacitance values are included into the substrate impedance information 46. In addition, the substrate parasitic element extraction section 32 derives coordinates of the contacts from the substrate structure data 42. In this manner, the substrate parasitic element extraction section 32 extracts, for example, a substrate impedance which includes well resistances Rw, a capacitance Csd between a source and a drain, and a well capacitance Cw, as shown in FIG. 8. As such, impedances between power supply wires are extracted based on power supply wire structure information, making it possible to automatically calculate an impedance related to power supply wires.

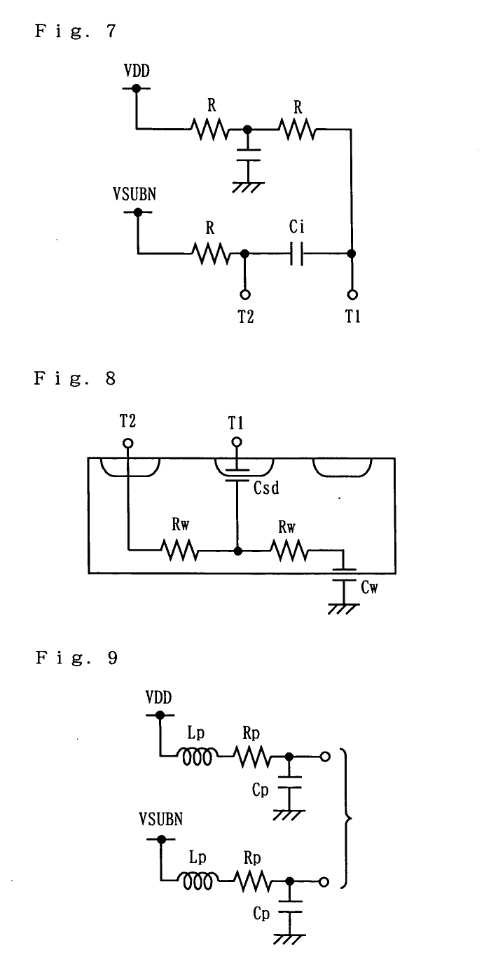

Package impedance information 47 includes values of resistance, capacitance, and inductance of a package, which have been analyzed based on the structure of the package, by utilizing, for example, an electromagnetic field simulator. The package impedance information 47 includes impedance of a circuit in which resistances Rp, capacitances Cp, and inductances Lp are connected in a manner as shown in FIG. 9.

The impedance combining section 33 obtains the power supply wire impedance information 21, based on the power supply wire parasitic impedance information 45, the substrate impedance information 46, and the package impedance information 47. For example, in the case where the circuit model as shown in FIG. 2 is used, the impedance combining section 33 combines the circuits shown in FIGS. 7, 8, and 9 in accordance with the circuit model shown in FIG. 2, and calculates impedance of a resultant circuit. At this time, the impedance combining section 33 performs a matching process between the power supply wire parasitic impedance information 45, the substrate impedance information 46, and the package impedance information 47 based on the coordinates of contacts, the coordinates of connections to the substrate, and the names of power supply wires. As such, impedances of partial circuits are combined to calculate an impedance between power supply wires, whereby it is possible to easily calculate the impedance of a power supply wire on a semiconductor integrated circuit composed of a plurality of components.

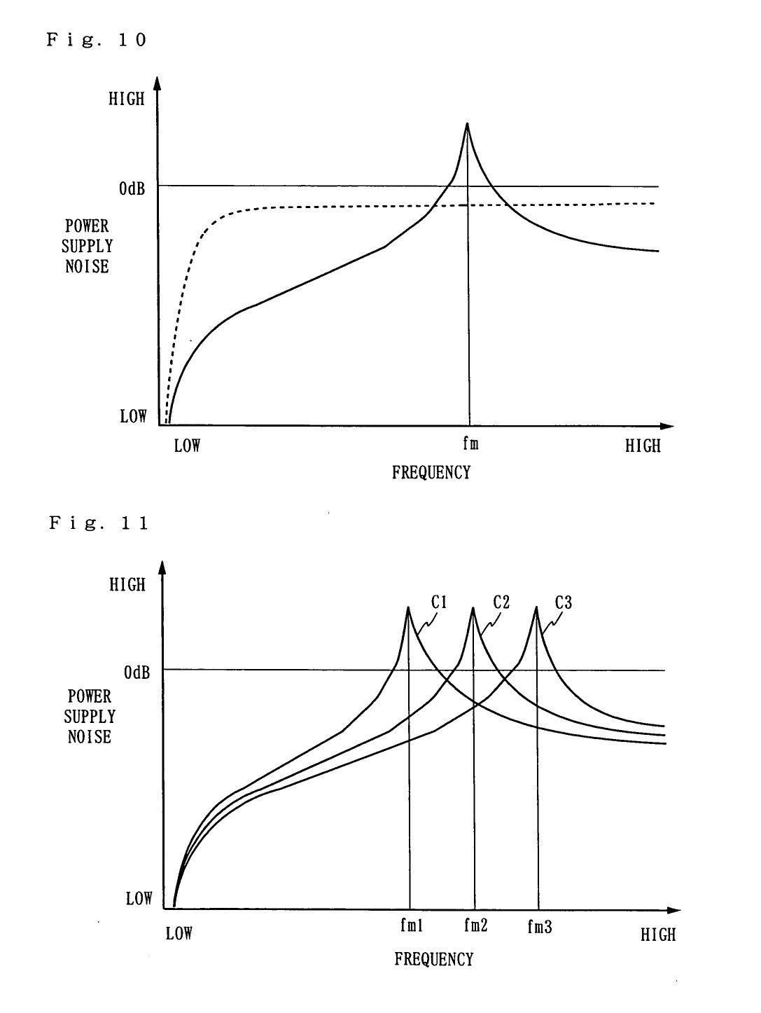

With reference to FIGS. 10 to 16, the details of the analysis section 12 are described below. As described above, the analysis section 12 uses, for example, an AC analysis function of a SPICE simulator to calculate a voltage amplification ratio between two points set in a circuit model, while changing a clock signal frequency. The analysis section 12 as described above can be used to obtain, as an analysis result 22, a relationship between a clock signal frequency and power supply noise.

FIG. 10 is a graph showing the analysis result 22 outputted from the analysis section 12. In FIG. 10, the horizontal axis shows frequency, and the vertical axis shows power supply noise. In FIG. 10, the solid line indicates power supply noise in the case where a wire capacitance between power supplies is taken into account, and the dashed line indicates power supply noise in the case where the wire capacitance between power supplies is not taken into account. The power supply noise analysis apparatus according to the present embodiment uses circuit models where, as illustrated in FIGS. 2 and 3, the wire capacitance between power supplies is taken into account. Accordingly, in the case of analyzing power supply noise while changing a clock signal frequency, as shown by the solid line in FIG. 10, the power supply noise is maximized when the clock signal frequency reaches a resonance frequency fm. In comparison, in conventional methods, where the wire capacitance between power supplies is not taken into account, as shown by the dashed line in FIG. 10, even if the power supply noise is analyzed while changing the clock signal frequency, it is not possible to obtain a clock signal frequency at which the power supply noise is maximized. As described above, the method for analyzing power supply noise according to the present embodiment takes into account the wire capacitance between power supply wires, whereby it is possible to recognize a resonance phenomenon in a circuit and thus easily obtain a frequency which is highly likely to cause the circuit to malfunction.

FIG. 11 is a graph, drawn in a manner similar to that of FIG. 10, that shows relationships between clock signal frequencies and power supply noise with respect to different wire capacitances between power supplies, which are C1, C2, and C3 (where C1<C2<C3). It is apparent from the analysis results shown in FIG. 11 that if the wire capacitance between power supplies changes from C1 to C2 to C3, the resonance frequency changes from fm1 to fm2 to fm3.

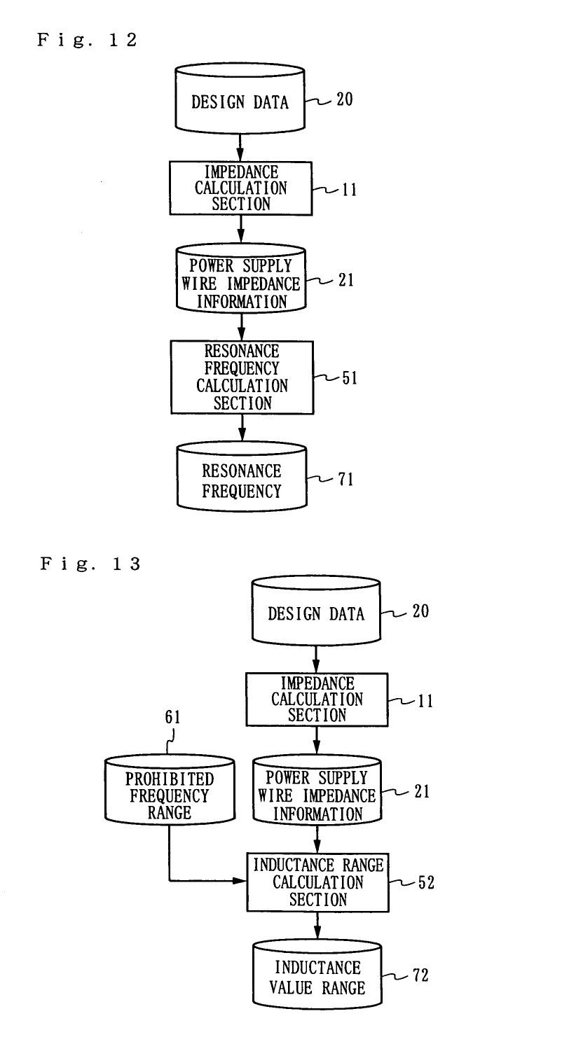

In the power supply noise analysis apparatus according to the present embodiment, the analysis section 12 may have a function different from that described above. FIG. 12 is a block diagram showing the details of another structure (a second structure) of the power supply noise analysis apparatus shown in FIG. 1. In FIG. 12, a resonance frequency calculation section 51 corresponds to the analysis section 12 shown in FIG. 1. Based on the power supply wire impedance information 21 obtained by the impedance calculation section 11, the resonance frequency calculation section 51 calculates a resonance frequency 71 of the semiconductor integrated circuit by equations as shown below. Specifically, assuming that impedance of a power supply wire calculated by the impedance calculation section 11 is expressed by the equation, |Z|=jωL+1/jωC (where L is an inductance value and C is a capacitance value), |Z| is minimized when ωL=1/ωC. Therefore, the resonance frequency fm is given by the equation, fm=1/(2π(LC)^{1/2}). When the clock signal frequency coincides with the resonance frequency fm, the power supply noise of the semiconductor integrated circuit is maximized.

In conventional AC analyses which are applied to printed circuit boards and so on, noise characteristics are analyzed with respect to a whole range of frequencies for which an analysis is to be conducted. The reason for this is that in design of a printed circuit board or the like, resonance occurs at a number of frequencies because impedances of a plurality of components affect the noise characteristics. In comparison, when power supply noise of a semiconductor integrated circuit is analyzed, the power supply noise is only insignificantly affected by impedances of components that are disposed outside and away from a chip. Therefore, based on the inductance value L and the capacitance value C which are included in the impedance calculated by the impedance calculation section 11, the resonance frequency fm of the semiconductor integrated circuit can be uniquely determined. Thus, the clock signal frequency at which the power supply noise is maximized can be obtained without conducting power supply noise analysis with respect to the whole range of frequencies for which the analysis is to be conducted.

FIG. 13 is a block diagram showing the details of still another structure (a third structure) of the power supply noise analysis apparatus shown in FIG. 1. In FIG. 13, an inductance range calculation section 52 corresponds to the analysis section 12 shown in FIG. 1. Based on the power supply wire impedance information 21 obtained by the impedance calculation section 11 and a given “prohibited frequency range” 61, the inductance range calculation section 52 calculates, by equations as shown below, a range of inductance values (hereinafter referred to as an “inductance value range” 72) which prevents a resonance frequency from falling within the prohibited frequency range 61. Specifically, assuming that impedance of a power supply wire calculated by the impedance calculation section 11 is expressed by the equation, |Z|=jωL+1/jωC (where L is an inductance value and C is a capacitance value), and that minimum and maximum values of the prohibited frequency range 61 are f1 and f2, respectively, f1 and f2 are given by the equations, f1=1/(2π(L1C)^{1/2}) and f2=1/(2π(L2C)^{1/2}). Therefore, boundary values L1 and L2 of the inductance value range 72 are given by the equations, L1=1/(C(2πf1)²) and L2=1/(C(2πf2)²), respectively. Accordingly, the inductance range calculation section 52 outputs, as the inductance value range 72, a range of values greater than the value L1 or less than the value L2. If the circuit design, the choice of a package, the design of a printed circuit board, and so on are performed such that an inductance component of the impedance related to a power supply wire falls within a calculated inductance value range, it is possible to ensure that the resonance frequency does not fall within the prohibited range from f1 to f2.

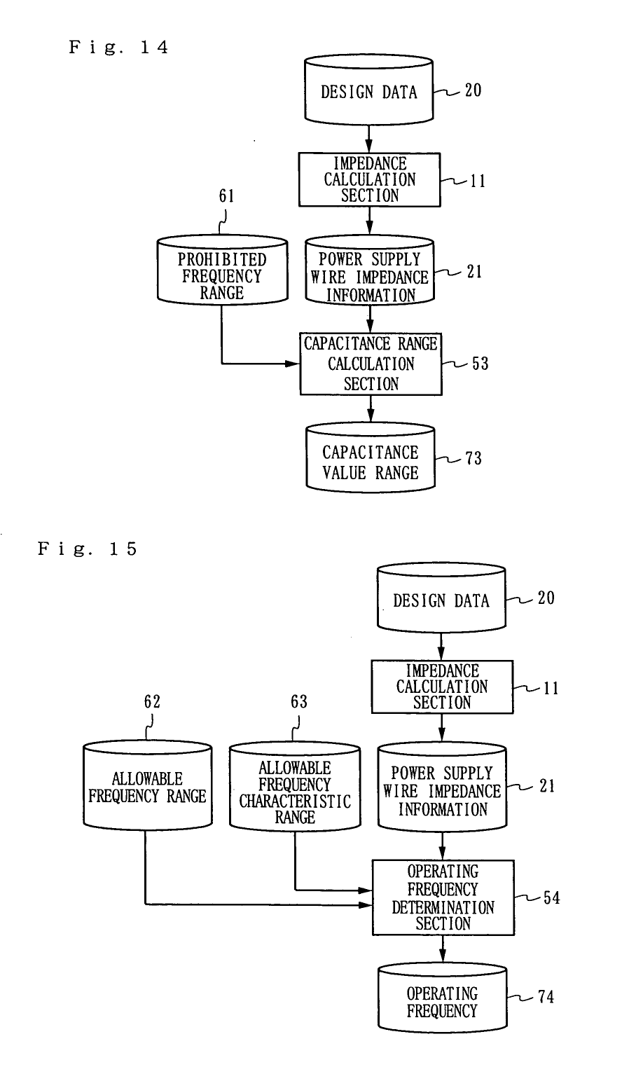

FIG. 14 is a block diagram showing the details of still another structure (a fourth structure) of the power supply noise analysis apparatus shown in FIG. 1. In FIG. 14, a capacitance range calculation section 53 corresponds to the analysis section 12 shown in FIG. 1. Based on the power supply wire impedance information 21 obtained by the impedance calculation section 11 and a given prohibited frequency range 61, the capacitance range calculation section 53 calculates, by equations as shown below, a range of capacitance values (hereinafter referred to as a “capacitance value range” 73) which prevents the resonance frequency from falling within the prohibited frequency range 61. Specifically, assuming that the impedance of a power supply wire calculated by the impedance calculation section 11 is expressed by the equation, |Z|=jωL+1/jωC (where L is the inductance value and C is the capacitance value), and that minimum and maximum values of the prohibited frequency range 61 are f1 and f2, respectively, f1 and f2 are given by the equations, f1=1/(2π(LC1)^{1/2}) and f2=1/(2π(LC2)^{1/2}). Therefore, boundary values C1 and C2 of the capacitance value range 73 are given by the equations, C1=1/(L(2πf1)²) and C2=1/(L(2πf2)²). The capacitance range calculation section 53 outputs, as the capacitance value range 73, a range of values greater than the value C1 or less than the value C2. If the circuit design, the choice of a package, the design of a printed circuit board, and so on are performed such that a capacitance component of the impedance related to a power supply wire falls within a calculated capacitance value range 73, it is possible to ensure that the resonance frequency does not fall within the prohibited range from f1 to f2. Note that in the structures shown in FIG. 13 and FIG. 14, the prohibited frequency range 61 is typically set so as to include an operating frequency and/or a harmonic frequency of a semiconductor integrated circuit.

FIG. 15 is a block diagram showing the details of still another structure (a fifth structure) of the power supply noise analysis apparatus shown in FIG. 1. In FIG. 15, an operating frequency determination section 54 corresponds to the analysis section 12 shown in FIG. 1. Based on the power supply wire impedance information 21 obtained by the impedance calculation section 11, a given “allowable frequency range” 62, and a given “allowable frequency characteristic range” 63, the operating frequency determination section 54 determines, as an operating frequency 74 of a semiconductor integrated circuit, a frequency which is within the allowable frequency range 62 and which keeps power supply noise within the allowable frequency characteristic range 63. If the operating frequency thus determined is used, it is possible to ensure that power supply noise of a semiconductor integrated circuit falls within a predetermined range of levels.

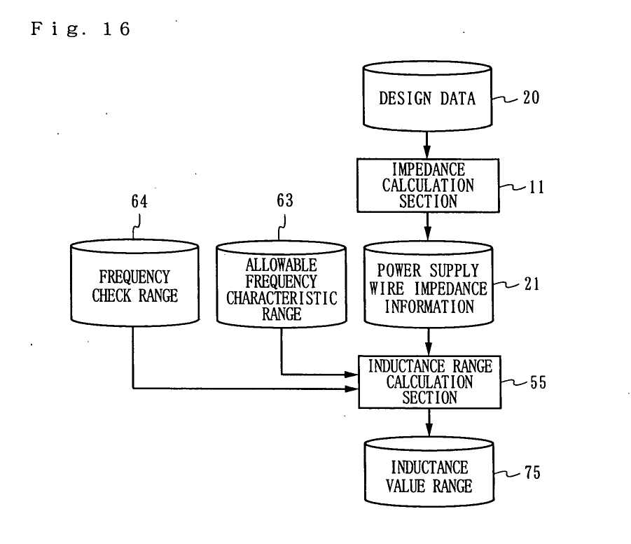

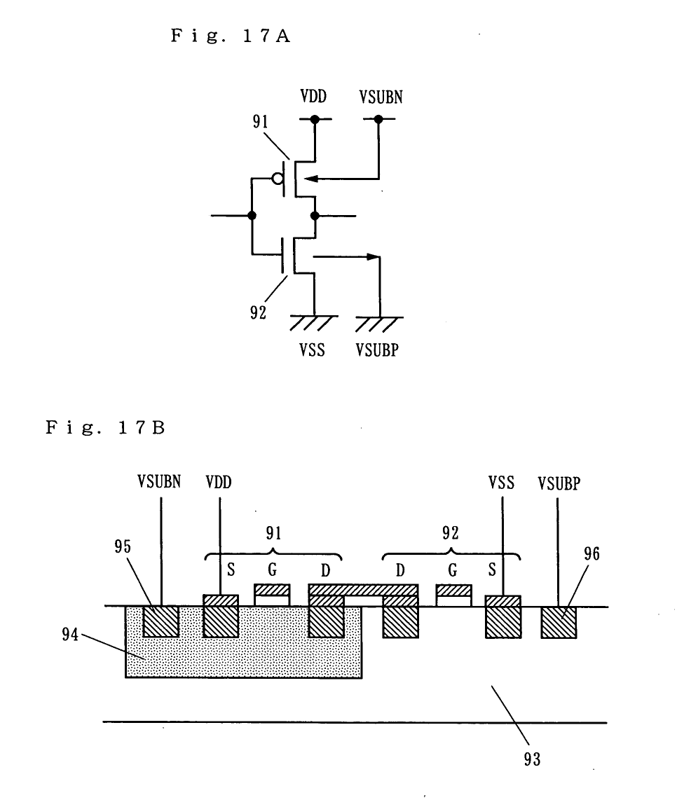

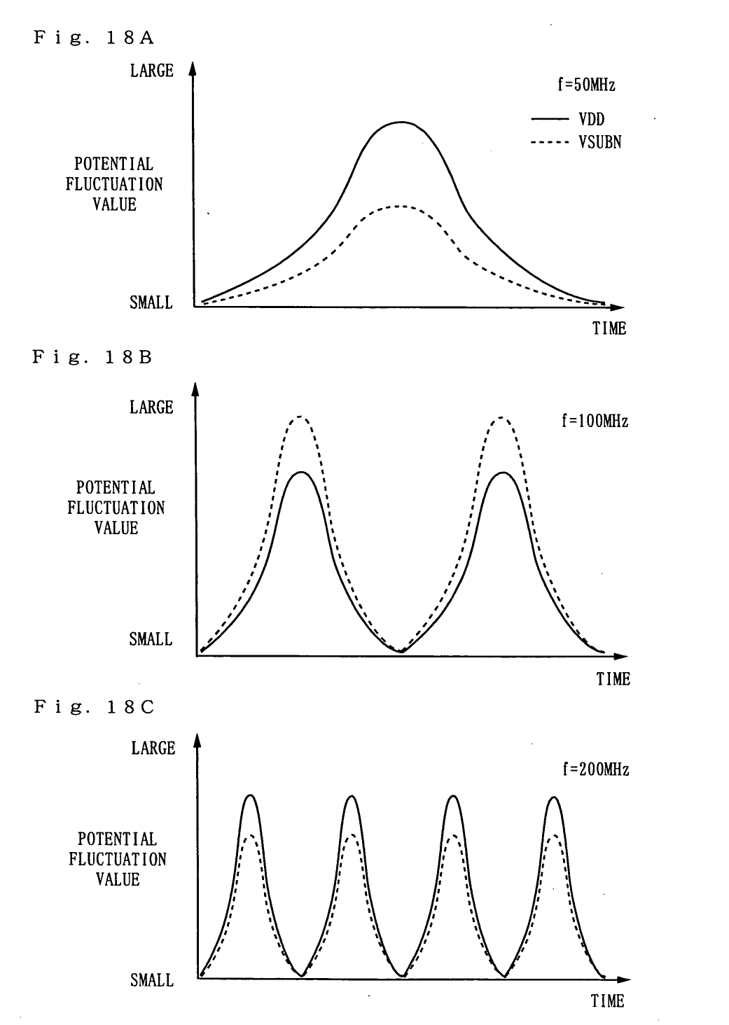

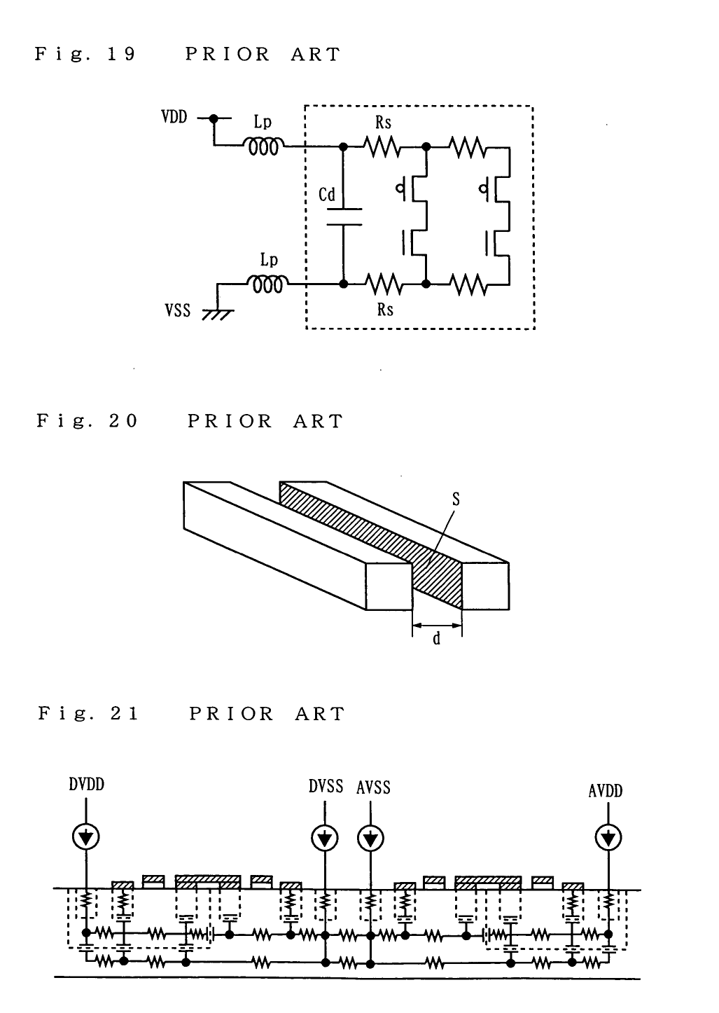

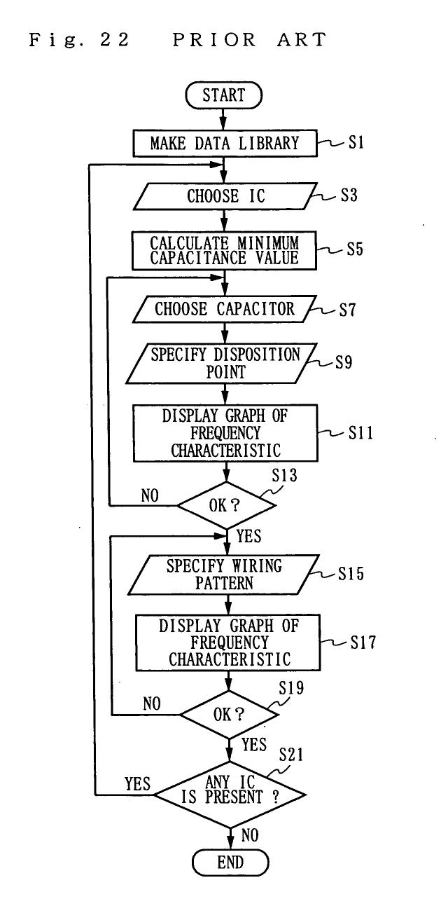

FIG. 16 is a block diagram showing the details of still another structure (a sixth structure) of the power supply noise analysis apparatus shown in FIG. 1. In FIG. 16, an inductance range calculation section 55 corresponds to the analysis section 12 shown in FIG. 1. Based on the power supply wire impedance information 21 obtained by the impedance calculation section 11, a given “frequency check range” 64, and a given “allowable frequency characteristic range” 63, the inductance range calculation section 55 calculates a range of inductance values (hereinafter referred to as an “inductance value range” 75) which keeps power supply noise within the allowable frequency characteristic range 63 in the frequency check range 64.

Instead of including the inductance range calculation section 55, the power supply noise analysis apparatus may comprise a range calculation section that calculates, with respect to at least one member selected from the group consisting of capacitance, inductance, and resistance values, a range which keeps power supply noise within the allowable frequency characteristic range 63 in the frequency check range 64. As described above, if a circuit design, the choice of a package, the design of a printed circuit board, and so on are performed in accordance with an inductance value, etc., calculated by the inductance range calculation section 55, it is possible to prevent power supply noise from being out of a given allowable range in a given frequency range.

In the structures shown in FIG. 15 and FIG. 16, the allowable frequency characteristic range 63 which is given to the analysis section 12 may be changed based on a delay constraint of a circuit design. This makes it possible to change the strictness of a power supply noise analysis in accordance with the strictness of the delay constraint.

As described above, in the power supply noise analysis method according to the present embodiment, the frequency characteristic of power supply noise is analyzed based on an impedance related to a power supply wire. Therefore, if a floor planning process has been completed and the structure of the power supply wire has been obtained, the process of power supply noise analysis can be performed even without a layout process having been completed. In addition, because only power supply wires are subjected to analysis, the process of power supply noise analysis can be performed with a small amount of calculation.

Moreover, by calculating an impedance between power supply wires which are substantially the same in potential, it is made possible to analyze power supply noise which is not analyzable by using conventional circuit models, i.e., power supply noise that is to be generated between a power supply and a substrate power supply or between a ground and a substrate ground in a semiconductor integrated circuit in which an additional power supply is used to control a circuit substrate voltage.

The power supply noise analysis method according to the present invention is executable in an early stage of a design process with a small amount of calculation. Thus, the method can be applied to a supply noise analysis of various kinds of semiconductor integrated circuits, especially to a power supply noise analysis of a semiconductor integrated circuit in which an additional power supply is used to control a circuit substrate voltage.

While the invention has been described in detail, the foregoing description is in all aspects illustrative and not restrictive. It is understood that numerous other modifications and variations can be devised without departing from the scope of the invention.

1. A method for analyzing power supply noise of a semiconductor integrated circuit, comprising:
an impedance calculation step of calculating an impedance related to a power supply wire based on design data of the semiconductor integrated circuit; and
an analysis step of analyzing a frequency characteristic of the power supply noise based on the calculated impedance.

2. The method according to claim 1, wherein the impedance calculation step calculates an impedance of a path including two or more power supply wires in the semiconductor integrated circuit.

3. The method according to claim 2, wherein,
the semiconductor integrated circuit has a first power supply wire having a relatively high potential and a second power supply wire having a relatively low potential, and
the impedance calculation step calculates an impedance of a path including the first and second power supply wires.

4. The method according to claim 2, wherein,
the semiconductor integrated circuit has a first power supply wire having a relatively high potential, a second power supply wire having a relatively low potential, and a third power supply wire having a potential substantially equal to that of the first power supply wire, and
the impedance calculation step calculates an impedance of a path including the first and third power supply wires.

5. The method according to claim 2, wherein,
the semiconductor integrated circuit has a first power supply wire having a relatively high potential, a second power supply wire having a relatively low potential, and a third power supply wire having a potential substantially equal to that of the second power supply wire, and
the impedance calculation step calculates an impedance of a path including the second and third power supply wires.

6. The method according to claim 2, wherein the impedance calculation step calculates an impedance including an inter-wire capacitance that exists on a path including two or more power supply wires.

7. The method according to claim 2, wherein the impedance calculation step calculates an impedance including a substrate impedance that exists on a path including two or more power supply wires.

8. The method according to claim 2, wherein the impedance calculation step calculates an impedance including an impedance of a package that is connected to two or more power supply wires.

9. The method according to claim 2, wherein the impedance calculation step calculates an impedance including an impedance of a printed circuit board that is connected to two or more power supply wires.

10. The method according to claim 2, wherein the impedance calculation step calculates an impedance of a path including two or more power supply wires that are separated by a resistance element, a substrate resistance, a capacitance element, a junction capacitance, or a well capacitance.

11. The method according to claim 2, wherein the impedance calculation step extracts an impedance of the path including two or more power supply wires, based on power supply wire structure information.

12. The method according to claim 11, wherein,
the semiconductor integrated circuit has a first power supply wire having a relatively high potential, a second power supply wire having a relatively low potential, and a third power supply wire having a potential substantially equal to that of the first power supply wire, and
the impedance calculation step extracts an impedance of a path including the first and third power supply wires, based on the power supply wire structure information.

13. The method according to claim 11, wherein,
the semiconductor integrated circuit has a first power supply wire having a relatively high potential, a second power supply wire having a relatively low potential, and a third power supply wire having a potential substantially equal to that of the second power supply wire, and
the impedance calculation step extracts an impedance of a path including the second and third power supply wires, based on the power supply wire structure information.

14. The method according to claim 2, wherein the impedance calculation step combines impedances of partial circuits based on a predetermined circuit model to calculate the impedance of the path including two or more power supply wires.

15. The method according to claim 1, wherein the analysis step calculates, based on the calculated impedance, a resonance frequency of the semiconductor integrated circuit.

16. The method according to claim 1, wherein the analysis step calculates, based on the calculated impedance, at least either a range of capacitance values or a range of inductance values, such that a resonance frequency of the semiconductor integrated circuit is kept out of a preset prohibited range.

17. The method according to claim 16, wherein the prohibited range is set so as to include at least either an operating frequency or a harmonic frequency of the semiconductor integrated circuit.

18. The method according to claim 1, wherein the analysis step calculates, based on the calculated impedance, a frequency range that keeps the power supply noise within a predetermined range of levels, and determines an operating frequency of the semiconductor integrated circuit from within the calculated frequency range.

19. The method according to claim 1, wherein based on the calculated impedance, the analysis step calculates, with respect to at least one member selected from the group consisting of capacitance, inductance, and resistance values, a range which keeps the power supply noise within a predetermined range of levels in a preset frequency range.

20. The method according to claim 18, wherein the predetermined range of levels changes based on a delay constraint of a circuit design.

21. The method according to claim 19, wherein the predetermined range of levels changes based on a delay constraint of a circuit design.
